(19) United States
(12) Patent Application Publication
(10) Pub. No.: US 2003/0209819 A1
(43) Pub. Date: Nov. 13, 2003

(54) Process for making micro-optical elements from a gray scale etched master mold

(76) Inventors: David R. Brown, Meridianville, AL (US); John P. Rauseo, Moulton, AL (US)

Correspondence Address: Patent Administrator, Mems Optical, Inc., 205 Import Circle, Suite 2, Huntsville, AL, 35806, US

(21) Appl. No.: 10/285,578

(22) Filed: Nov. 1, 2002

Related U.S. Application Data
(60) Provisional application No. 60/330,906, filed on Nov. 2, 2001.

(51) Int. Cl. B29D 11/00; G03F 7/16; G03F 7/20; G03F 7/40

(52) U.S. Cl. 264/2.5; 430/290; 430/296; 430/320; 430/321

(57) ABSTRACT

Embodiments of the invention provide methods and processes for creating and using high precision molds for creating micro-optical elements, such as micro-lenses. A master mold is created using one of at least gray scale technologies or direct write lithography to provide highly accurate micro-optical contours on a substrate or resist layer upon which the master mold is formed. The master mold may be used to create secondary molds for use in production of highly precise micro-optical elements from various materials.

### BACKGROUND

1. Field of the Invention

This invention relates generally to fabricating masters, and more specifically to the process for fabricating micro-optical elements or micro-lenses for use in mass replication from a gray scale etched master mold.

2. Background of Related Art

A variety of processes exist for fabricating master molds for making injection-molded plastics. For example, laser-direct write is a process that is used to create binary pits. This method is used by the compact disc industry for fabricating the initial master in photo resist. This method, however, is very specific in its application and has limited uses outside the data storage industry.

One process for fabricating master molds involves diamond turning, or diamond ruling engines. This method uses a diamond-cutting tool mounted on a complex staging system. Selected diamonds, whose crystal axis is oriented for optimum behavior, are used to shape the structure. A material is placed on the staging system and the diamond tip is used to mill or cut away the material to leave the desired master mold structure. Diamond turning and ruling engines are, however, usually limited in the complexity of the structures they can produce. Further, the resolution and the fidelity on these machines are limiting factors in producing a micro-lens.

Another process for fabricating a master mold involves binary lithography. This process uses standard binary lithography and etching cycles to produce a step-wise approximation of the desired surface topography and has many additional process steps that produce a limited range of surface structures. This process may be problematic in fabricating certain structures, however, as this process would not be able to effectively produce a smooth deep structure desired in precision micro-devices.

As such, there is a need for a process that is capable of producing a smooth, deep structure that has high resolution and fidelity, such that a master mold may be created for micro-devices, such as for a micro-lens.

### SUMMARY OF THE INVENTION

In embodiments of the present invention, gray scale technologies are utilized in conjunction with a coating process such as electroplating to produce high quality, accurate master molds for use on the micro-scale level to, in turn, mold micro-lenses out of plastic material.

In accordance with one embodiment of the present invention, a master mold is created by providing a providing a resist layer on a substrate and creating a desired pattern in the resist using gray scale lithographic or direct write lithographic processes. A hard coating material is provided on the patterned resist. The substrate and resist are removed leaving the precision master mold. The master mold may then be used to mold subsequent molds or for use in creating precision micro-lenses or other gray scale structures.

In accordance with a second embodiment of the present invention, a master mold is created by providing a providing a resist layer on a substrate and creating a desired pattern in the resist using gray scale lithographic or direct write lithographic processes. The substrate is etched in accordance with the pattern in the resist. A hard coating is provided on the substrate thus creating a precision master mold.

### BRIEF DESCRIPTION OF THE DRAWINGS

The accompanying drawings, which are incorporated in and constitute a part of the specification, illustrate embodiments of the present invention and, together with the description, explain the principles of the invention, wherein:

FIG. 1 depicts an exemplary image of a master mold consistent with the principles of the present invention;

FIGS. 2(a)-2(b) depict exemplary images of a process for creating a master mold consistent with the principles of the present invention.

FIG. 3 depicts an exemplary image of another embodiment of a master mold consistent with the principles of the present invention;

FIG. 4 depicts an exemplary flow diagram of the steps included in a process for fabricating a micro-optical element, consistent with the principles of the present invention;

FIG. 5 depicts an exemplary flow diagram of another embodiment of the process for manufacturing a micro-optical element consistent with the principles of the present invention;

FIG. 6 depicts an exemplary image depicting secondary molds being manufactured by an original master; and

FIG. 7 depicts an exemplary image depicting a secondary mold producing plastic parts using molding.

### DETAILED DESCRIPTION

In accordance with the principles of the invention, as embodied and broadly described herein, processes consistent with the principles of the invention may be used to produce a micro-optical element or other lithographically produced structure having gray scale contours. One embodiment of the process generally includes providing an etchable substrate; etching the substrate to produce a desired micro-optical element contour on the etched substrate; coating the desired micro-optical element contour with a hard coating; removing the etched substrate from the hard coating to form a mold master from the hard coating; and stamping or molding micro-optical elements from the master mold. Additionally, the master micro-optical element mold may be used to mold secondary molds that can, in turn, be used to mass-produce parts without wearing down the original master mold.

In accordance with another embodiment consistent with the principles of the invention, as embodied and broadly described herein an alternative process is provided for manufacturing a master mold. The process generally includes providing an etchable substrate; etching the substrate to produce a desired micro-optical element contour on the etched substrate; coating the desired micro-optical element contour with a hard coating; and reproducing at least one micro-optical element using at least one of a stamping and molding process. Additionally, the master mold may be used to create secondary molds that can be, in turn, used to mass-produce micro-optical elements or micro-lenses without wearing down the original.

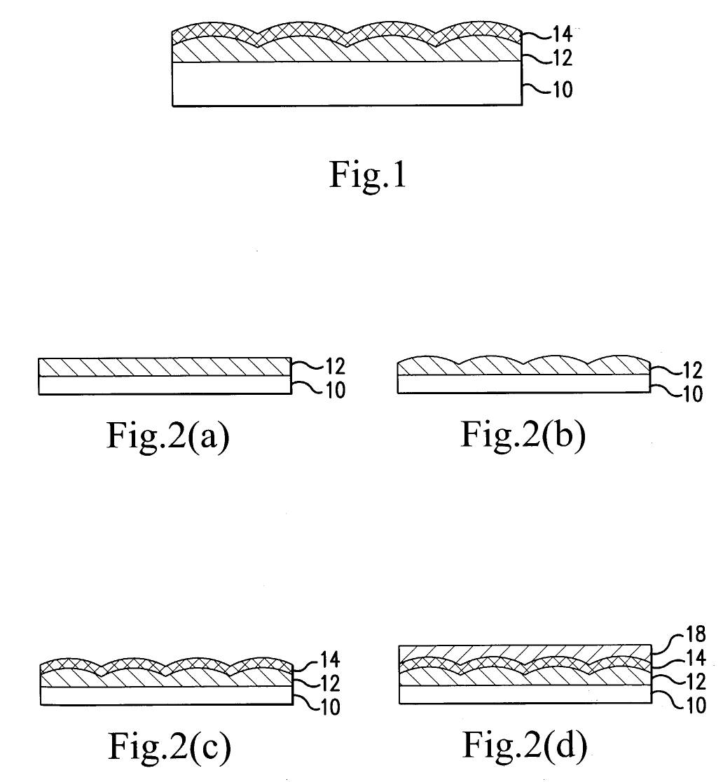

FIG. 1 depicts an exemplary image of a master mold. FIG. 1 includes wafer or substrate 10, resist 12 and coating 14. The structure depicted in FIG. 1 can be generated using a gray-scale lithography process as set forth in U.S. Pat. Nos. 5,482,800 and 5,310,623 to Gal, which are fully incorporated herein by reference. In this process a binary mask having a plurality of openings is produced with the area of the openings for a given location related to exposure density and contour level. Other gray-scale processes, such as those using High Energy Beam Sensitive (HEBS) may also be used. In such a HEBS process the HEBS glass is exposed with a relatively high energy irradiation beam to produce a selective darkening in the HEBS glass in relation to the applied beam intensity. The exposed HEBS glass may then be used as a master mask to expose a photosensitive material to facilitate gray scale etching of a desired contour. Alternatively, direct beam writing techniques may be used to expose a photosensitive material to produce a gray scale contour.

The gray scale lithography process uses a gray scale mask to pattern a photoresist on a substrate, which is subsequently etched to form curved shapes. Patterning the photoresist to form a photomask layer can be performed using only a single gray scale mask. Alternatively, patterning the photoresist to produce a variable thickness photoresist layer can be accomplished utilizing two gray scale masks.

By varying the thickness of the photoresist at various locations, a pattern is created which can be replicated in the substrate material. When the photoresist is exposed an impression of the desired pattern in the developed photoresist is produced.

The image impression in the photoresist is produced by exposing the photoresist material to light of a selected wavelength through the gray scale mask, transmitted through openings in the exposure mask for a selected time period. The light is usually ultraviolet light. The exposed photoresist material is subsequently processed to procure the desired object on a substrate material using an etching method such as RIE (Reactive Ion Etching) or DRIE (Deep Reactive Ion Etching).

It can be appreciated by one of ordinary skill in the art that the structure depicted in FIG. 1 may also be fabricated using a direct write gray scale process. Direct write is a process of pattern transfer in which the elements comprising a pattern are formed serially rather than simultaneously through a mask. The technique includes scanning a beam of electrons across a surface covered with a resist film sensitive to those electrons, thus depositing energy in the desired pattern in the resist film. The beam can be modulated in a variety of ways to vary the exposure to produce complex non-binary surface topologies. The benefits of utilizing this process is that it is capable of very high resolution, almost to the atomic level and it is a flexible technique that can work with a variety of materials and an almost infinite number of patterns.

While the process of the present application generally uses a resist, it can further be appreciated by one of ordinary skill in the art that the pattern or contour may be etched directly into the substrate. It can further be appreciated that the initial master mold may be provided in material other than the traditional photoresist or electron beam resist, such as polyamide.

Furthermore, a process may be used for providing a pattern in a photoresist layer or similar material, which utilizes accurate molds for transferring a pattern to the photoresist, as described in U.S. patent application Ser. No. 10/115,992 to Harchanko et al, hereby fully incorporated by reference.

Coating 14 may be any suitablely hard material, for example a plated layer of nickel fabricated using an electroplating technique whereby the wafer or substrate 10 with the exposed resist 12 is placed in an electroplating tank and nickel is grown on the surface of the resist. It can be appreciated by one of ordinary skill that other suitable substances may be used.

It can be appreciated by one of ordinary skill in the art that other processes for fabricating the coating 14 may be utilized as would occur to one of ordinary skill in the art. For example, instead of electroplating, sputtering may be employed whereby a target material is bombarded with argon ions. The displaced molecules of the target material are then deposited on the wafer surface. Another process that may be utilized for fabricating coating 14 is to employ a chemical vapor deposition process, in which a controlled chemical reaction produces a thin surface film.

FIGS. 2(a)-2(d) depict an embodiment of a process for fabricating a master mold. FIG. 2(a) illustrates a substrate 10 with a resist or similar material 12 deposited thereon. Upon depositing the resist 12 on the substrate 10, a gray scale process, as discussed above, is used to derive a desired pattern within the resist 12. FIG. 2(b) illustrates the substrate 10 and resist 12 with the desired pattern. Upon achieving the desired pattern within the resist 12, a hard coating 14, as illustrated in FIG. 2(c) is grown on the resist 12. The surface of the hard coating 14, which faces the resist 12, is the molding surface of the master mold. A backing 16 may be provided for the master mold, as illustrated in FIG. 2(d) in order to provide additional support for the master mold in the replication process. The backing 16 may be fabricated using any suitable materials known to one of ordinary skill in the art.

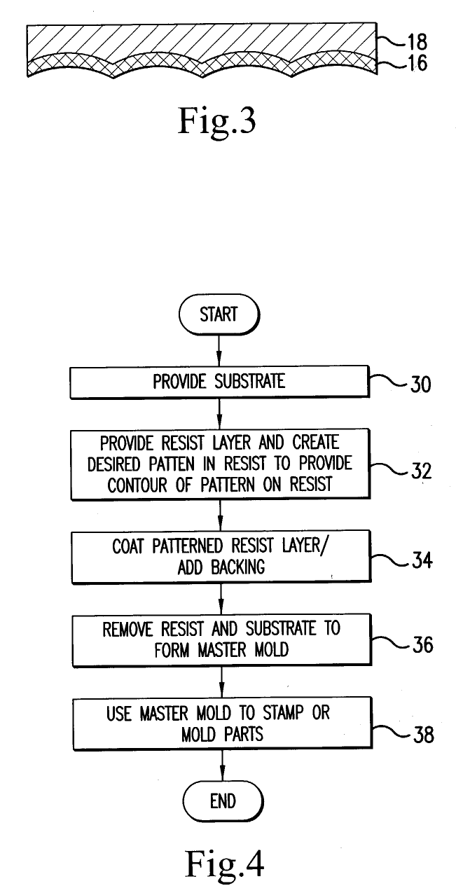

Upon placement of the backing 16, the resist 12 and substrate 10 are removed leaving the hard coating 14 and backing 16, thus creating the master mold. FIG. 3 depicts the hard coating 14 and backing 16 with the resist 12 and substrate 10 removed. The master mold may then be used to mass-replicate precision plastic parts. The master mold may further be used to create secondary molds.

FIG. 4 depicts an exemplary flow diagram of the steps included in the process for manufacturing a micro-optical element or micro-lens using a molding technique consistent with an embodiment of the invention. As shown in FIG. 4, a substrate is provided for (Step 30). A resist is provided on the substrate and a pattern is created in the resist to provide a contour of a micro-optical element (Step 32). This may be done using a number of different processes, including a gray-scale lithography process or a direct write lithography process. The contour is then coated with a hard coating (Step 34). This coating may be formed using an electroplating technique using nickel or other mold materials. It can be appreciated by one of ordinary skill in the art that a sputtering or a chemical vapor deposition process may be used instead of the electroplating technique. Further, after providing a hard coating, a backing may be added to the hard coating in this step to provide support for the master mold.

After the surface is coated, the substrate and resist are removed to form the master mold (Step 36). This may be accomplished utilizing a stripping process that uses a chemical solvent known to one of ordinary skill. The master may then be used to stamp or mold parts in a suitable material (Step 38). A suitable material for optical elements might, for example, be an optical grade plastic or another material that may be softened sufficiently to enable molding or stamping. For example, the master mold may be used in an injection-molding machine where the mold is used as one of the walls of a high-pressure chamber into which plastic is injected. Alternatively, the master mold may further be used in an embossing machine. It can be appreciated by one of ordinary skill in the art that sol-gel glass may be used instead of plastic.

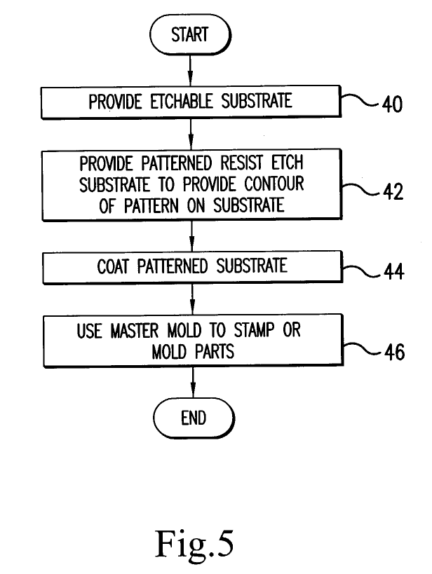

FIG. 5 depicts an exemplary flow diagram of another embodiment of the process for manufacturing a micro-optical element consistent with the principles of the present invention. In this embodiment, the substrate may be etched with the resist design and a hard coating provided on the substrate. As shown in FIG. 5, an etchable substrate is provided (Step 40). A patterned resist is provided on the substrate and the substrate is then etched to provide a contour on a micro-optical element (Step 42). This may be done using a number of different processes, including a gray-scale lithography process with direct or indirect writing. In an embodiment of the invention, the etched substrate may be used as the master mold. In another embodiment, the micro-optical contour created in the substrate may then be coated with a hard coating, which forms the master mold (Step 44). This coating may be formed using an electroplating technique using nickel or other mold materials. It can be appreciated by one of ordinary skill in the art that a sputtering or a chemical vapor deposition process may be used instead of the electroplating technique. The master mold thus prepared may then be used to stamp or mold parts out of a plastic or other suitable material as previously described (Step 46). For example, the master mold may be used in an injection-molding machine where the mold is used as one of the walls of a high-pressure chamber into which plastic is injected. Alternatively, the master mold may further be used in an embossing machine. It can be appreciated by one of ordinary skill in the art that sol-gel glass may be used instead of plastic.

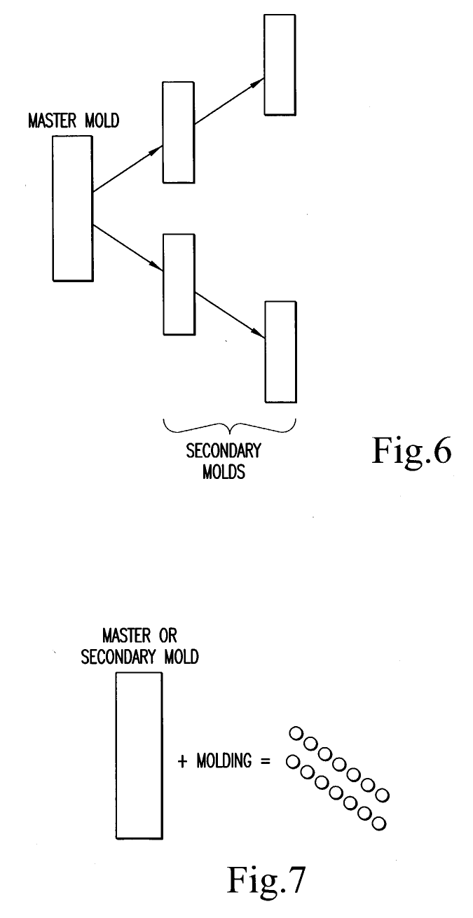

FIG. 6 depicts an exemplary image of secondary, or daughter molds that are produced from the original master mold. Once the master mold element is manufactured, a secondary, or daughter mold may be produced from the original master mold in order to avoid wearing the original master mold. This may be accomplished using suitable techniques known to one of ordinary skill in the art. For example, the secondary mold may be produced using a stamping process. The secondary or daughter mold may be used in the molding or embossing machine as already described.

FIG. 7 depicts an exemplary image of the secondary mold used in creating parts from a suitable material. For example, when the secondary mold is used in a molding machine and molding is applied to the secondary mold using techniques known to one of ordinary skill, parts are produced, such as highly precise micro-lenses made from suitable optical plastic.

Modifications and adaptations of the invention will be apparent to those skilled in the art from consideration of the specification and practice of the invention disclosed herein. It is intended that the specification and examples be considered as exemplary only, with a true scope and spirit of the invention being indicated by the following claims.

What is claimed:

1. A process for manufacturing an optical element comprising:
providing a substrate;
depositing a layer of photoresist on the substrate;
creating a desired pattern in the photoresist using a process for varying the thickness at specific locations on the photoresist to produce a gray scale contoured photoresist;
coating the gray scale contoured photoresist with a hard coating to form a surface having the desired gray scale contour;
providing a backing over the hard coating
removing the substrate and photoresist from the hard coating to form a master mold from the hard coating; and
reproducing at least one optical element using the mold master by stamping or molding.

2. The process of claim 1, wherein the desired pattern is created using at least one of a gray-scale lithography and a direct write lithography.

3. The process of claim 2, wherein a high energy beam sensitive procedure is used in conjunction with the gray scale lithography.

4. The process of claim 1, wherein the mold master is used to produce at least one secondary mold from the master mold and wherein the secondary mold is used in stamping or molding the optical element.

5. The process of claim 1, wherein the secondary mold is used to reproduce at least one optical element using at least one of a stamping and molding process.

6. The process of claim 1, wherein the coating includes nickel.

7. The process of claim 1, wherein the coating and backing are made from the same material.

8. The process of claim 1, wherein hard coating may be deposited using at least one of electroplating, sputtering and chemical vapor deposition.

9. The process of claim 1, wherein the pattern created in the photoresist is provided by a patterned mold.

10. A process for manufacturing a master optical element comprising:
providing an etchable substrate;
depositing a layer of photoresist on the substrate;
creating a desired pattern in the photoresist using a process for varying the thickness at specific locations on the photoresist to produce a gray scale contoured photoresist;
etching the substrate to produce a desired optical element contour on the etched substrate to create a master mold; and
reproducing at least one optical element from the master mold using at least one of a stamping and molding process

11. The process of claim 10, wherein the substrate is etched using at least one of a grayscale lithography and a direct write lithography.

12. The process of claim 11, wherein a high energy beam sensitive procedure is used in conjunction with the gray scale lithography.

13. The process of claim 10, wherein the master mold is used to produce at least one secondary mold from the master mold.

14. The process of claim 10, wherein the secondary mold is used to reproduce at least one optical element by stamping or molding.

15. The process of claim 10, wherein the coating includes nickel.

16. The process of claim 10, further including the step of coating the etched substrate with a hard coating in accordance with the optical element contour.

17. The process of claim 10, wherein the pattern created in the photoresist is provided by a patterned mold.
